(19) United States
(12) Patent Application Publication
(10) Pub. No.: US 2024/0087979 A1
(43) Pub. Date: Mar. 14, 2024

(54) Carrier Substrate

(71) Applicant: Solid-tech Co., Ltd., Hsinchu County (TW)

(72) Inventors: Tzu Chien Hung, Hsinchu County (TW); Chun-Teng Ko, Hsinchu County (TW); Bomin Tu, Hsinchu County (TW); Zhengyu Lee, Hsinchu County (TW)

(21) Appl. No.: 18/511,390

(22) Filed: Nov. 16, 2023

Related U.S. Application Data
(63) Continuation-in-part of application No. 18/509,814, filed on Nov. 15, 2023.
(60) Provisional application No. 63/409,416, filed on Sep. 23, 2022.

(51) Int. Cl. H01L 23/373; H01L 21/48; H01L 23/00; H01L 23/13

(52) U.S. Cl. CPC H01L 23/3735; H01L 21/4846; H01L 23/13; H01L 24/29; H01L 24/32; H01L 2224/29109; H01L 2224/29111; H01L 2224/29113; H01L 2224/29144; H01L 2224/29147; H01L 2224/32238; H01L 2924/01322; H01L 2924/0133; H01L 2924/0134; H01L 2924/12042; H01L 2924/13055

(57) ABSTRACT

This invention provides a carrier or submount for high power devices packaging and a method for forming the carrier or submount. The carrier comprises a thermal conductive ceramic substrate with at least one recess region, a patterned adhesion layer on the substrate, a heat dissipation layer on the patterned adhesion layer, a conformal cover layer enclosing the heat dissipation layer and the adhesion layer, a diffusion barrier layer on the conformal cover layer, and an eutectic bonding layer on the diffusion barrier layer. The substrate includes a first region for bonding high power device, a second region for wire-bonding, and a third region for heat sink. The first region and second region are on a first surface of the substrate, and the third region is one the second surface, opposite to the first surface, of the substrate.

### FIELD OF THE INVENTION

The invention relates to a carrier substrate, and more particularly to a submount for packaging high power devices. However, it would be recognized that the invention has a much broader range of applicability.

### BACKGROUND OF THE INVENTION

Electronic devices, such as IC (Integrated Circuits) or LED (Light Emitting Diode) chips, are packaged or assembled on a carrier or submount. The package or assembly will be mounted on a PCB (Printed Circuits Board) as a module or a system. High power devices, which generate lots of heats, provide significant applications in our daily life, such as switch or rectifier. Current commercially available high power devices may include diodes, LASER diodes, SCR (Silicon-controlled rectifier), thyristor, GTO (Gate turn-off thyristor), triac, BJT (Bipolar junction transistor), power MOSFET (Metal-oxide-semiconductor field effect transistor), IGBT (Insulated-gate bipolar transistor), MCT (MOS-controlled thyristor), and IGCT (Integrated gate-commutated thyristor). Wide-band gap semiconductor devices, such as GaN and SiC transistors, are now lively discussion due to fast charging electronic devices and electrical vehicle. Current LASER diodes are very important in many applications, such as LASER printer, CD/DVD player, LASER pointer, optical fiber data transmission or communication, optical computations, analog broadband signal transmission, absorption spectroscopy, biological tissue analysis, chip scale atomic clock, Lidar for cellphone cameras, structured light (e.g. the “dot projector” for iPhone X), Lidar for automobile collision avoidance, computer mouse, machining in the cutting or welding materials, military applications, barcode scanners, thermometers, holograms, or LASER surgery.

High power devices should be packaged or assembled with better heat dissipation. For the IGBT, GaN or SiC high power devices, heats are generated more and more according to the market demand. The power generated by the high power devices may reach 5 W/mm², or even more, which is larger than 3 W/mm² generated by LED. Thus, thermal strain and stress, heat dissipation, carrier or submount protection, electric conductivity under high temperature, and other considerations must be included in the design of carrier or submount.

However, package or assembly for high power devices still has issues in heat dissipation due to the carrier or submount in the package can not tolerate or afford more and more heats generated by the power devices. The heat issues may incur thermal strain and stress such that high power device may fail due to the wire may be broken caused by the mismatch thermal expansion between high power device and carrier. High temperature may cause metals on the carrier oxidation more easily and the internal resistance may be increased. Different metals me be diffused with each other more easier at high temperature also. Thus there will be some limitations to applications of the high power devices in package or module.

Accordingly, it is important to provide a carrier or submount matching next decade requirement for packaging power devices.

### BRIEF SUMMARY OF THE INVENTION

The object of this invention is to provide a carrier substrate for packaging high power devices.

It is an object of this invention to provide layers with matched thermal expansion coefficients in a carrier.

It is an object of this invention that thermal expansion coefficients of the heat dissipation layer is adjustable.

It is an object of this invention that heat dissipation layer can be protected by a conformal cover layer from oxidation or erosion.

It is an object of this invention to provide a better life and duration of a carrier or submount.

Accordingly, the invention therefore provides a carrier for packaging a power device, which comprises a thermal conductive ceramic substrate with at least one recess region, an adhesion layer patterned on a first and a second regions on a first surface and a third region on a second surface of the substrate, a heat dissipation layer patterned on the adhesion layer, a conformal cover layer for enclosing the adhesion layer and the heat dissipation layer, a diffusion barrier layer on the first region of the conformal cover layer, and an eutectic bonding layer on the diffusion barrier layer. The second surface is opposite to the first surface.

The present invention also provides a method for forming a carrier for packaging a power device, which comprises steps of providing a thermal conductive ceramic substrate with at least one recess region; forming a patterned adhesion layer on a first region on a first surface of the substrate, a second region on the first surface of the substrate, and a third region on a second surface of the substrate, the second surface opposite to the first surface by sputtering, evaporating, or electroless plating; forming a heat dissipation layer patterned on the adhesion layer by plating; forming a conformal cover layer for enclosing the adhesion layer and the heat dissipation layer; forming a diffusion barrier layer on the first region of the conformal cover layer by sputtering, evaporating, or plating; and forming an eutectic bonding layer on the diffusion barrier layer.

In a preferred embodiment, a material of the thermal conductive ceramic substrate is selected from a group consisting of AlN, AlO, BeO, SiC, SiN, and BN.

In a preferred embodiment, a material of the adhesion layer is selected from a group consisting of Rh, Ru, and Pt.

In a preferred embodiment, a material of the adhesion layer includes Cu, Ti, W, Pd, Mo, Rh, Ru, Pt, and alloy thereof.

In a preferred embodiment, the adhesion layer includes a layered structure of Mo/Cu, Ti/Cu, TiW/Cu, or Ti/Pt/Cu.

In a preferred embodiment, a material of the heat dissipation layer is selected from the group consisting of Cu, Ni, and alloy thereof.

In a preferred embodiment, a minute element is applied to the heat dissipation layer to match thermal expansion of the power device.

In a preferred embodiment, a material of the minute element is selected from a group consisting of Co, Fe, Ni, DLC, C, Si, and Ge.

In a preferred embodiment, a material of the conformal cover layer includes Ni/Au, Pt/Au, Pd/Au, Ni/Pt/Au, or Ni/Pd/Au.

In a preferred embodiment, a surface of the conformal layer on the second region is roughness.

In a preferred embodiment, a material of the diffusion barrier layer is selected from a group consisting of Pt, Rh, Ru, and Mo.

In a preferred embodiment, a material of the bonding pad is AuSn SnAgCu or InAuBiSn alloy.

The present invention also provides a carrier for packaging a power device, which comprises a thermal conductive ceramic substrate with at least one recess region, an adhesion layer patterned on a first and a second regions on a first surface and a third region on a second surface of the substrate, a heat dissipation layer patterned on the adhesion layer, a cover layer for enclosing the adhesion layer and the heat dissipation layer, a diffusion barrier layer on the first region of the conformal cover layer, and an eutectic bonding layer on the diffusion barrier layer. A thickness of said substrate matches thermal expansion of the power device. The second surface opposite to the first surface.

In a preferred embodiment, a thickness difference ratio between said heat dissipation layer on the first region and said heat dissipation layer on the second region is less than 5%.

In a preferred embodiment, a thickness difference ratio between said heat dissipation layer on the first region and said heat dissipation layer on the third region is between about 0.8 to 1.2.

In a preferred embodiment, a volume combined said heat dissipation layer on the first region and said heat dissipation layer on the second region is close to a volume of said heat dissipation layer on the third region.

The present invention may further comprise at least one recess region in the third region.

In a preferred embodiment, a portion of the first recess region is misaligned to a position of the power device bonded on the eutectic bonding layer.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The present invention will be readily understood by the following detailed description in conjunction with the accompanying drawings, wherein the same or like reference numerals designate the same or like structural elements, and in which:

FIG. 1 is a schematic illustration of cross-sectional view of one carrier substrate in accordance with one embodiment of the present invention;

FIG. 2 is a schematic illustration of cross-sectional view at various stages during the formation of the carrier substrate in accordance with one embodiment of the present invention;

FIG. 3 is a schematic illustration of cross-sectional view at various stages during the formation of an adhesion layer on the carrier substrate in accordance with one embodiment of the present invention;

FIG. 4 is a schematic illustration of cross-sectional view at various stages during the formation of a heat dissipation layer on the carrier substrate in accordance with one embodiment of the present invention;

FIG. 5 is a schematic illustration of cross-sectional view at various stages during the formation of a conformal cover layer on the carrier substrate in accordance with one embodiment of the present invention;

FIG. 6 is a schematic illustration of cross-sectional view of a diffusion barrier layer and an eutectic layer on the carrier substrate in accordance with another embodiment of the present invention;

FIG. 7 is a schematic illustration of cross-sectional view of a diffusion barrier layer and an eutectic layer on the carrier substrate in accordance with another embodiment of the present invention;

FIGS. 8A and 8B are schematic illustrations of top view of a diffusion barrier layer and an eutectic layer on the carrier substrate in accordance with two embodiments of the present invention;

FIG. 9 is a schematic illustration of cross-sectional view of a diffusion barrier layer and an eutectic layer on the carrier substrate in accordance with another embodiment of the present invention;

FIG. 10 is a schematic illustration of cross-sectional view of a diffusion barrier layer and an eutectic layer on the carrier substrate in accordance with another embodiment of the present invention;

While the invention is susceptible to various modifications and alternative forms, specific embodiments thereof are shown by way of example in the drawings and may herein be described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE INVENTION

As used herein, the term “substrate”, “carrier” or “submount” generally refers to plates formed of a semiconductor or non-semiconductor material. Examples of such a semiconductor or non-semiconductor material include, but are not limited to, monocrystalline silicon, silicon carbide, gallium arsenide, indium phosphide, sapphire, ceramic, glass, and PCB.

Such substrates, carrier or submount may be commonly found and/or processed in semiconductor or MEMS (Micro Electro Mechanical Systems) fabrication facilities. A bonding substrate refers to a plate with circuits and bonding pads thereon for receiving electronic devices.

For the substrate, one or more layers may be formed upon the substrate, carrier or submount. Many different types of such layers are known in the art, and the term substrate, carrier or submount as used herein is intended to encompass a board on which all types of such layers may be formed. One or more layers formed on a substrate, carrier or submount may be patterned. For example, a substrate, carrier or submount may include a plurality of circuits, each having patterned features. Formation and processing of such layers of material may ultimately result in completed devices.

Steps of the process flow in the present invention should be exchangeable generally, unless a logical sequence is required.

The conductive type of semiconductor in the present invention, such as n-type or p-type conductivity in the semiconductor layer, should be exchangeable.

In the present invention, power devices also refer to high power devices.

Various example embodiments of the present invention will now be described more fully with reference to the accompanying drawings in which some example embodiments of the invention are shown. Without limiting the scope of the protection of the present invention, all the description and drawings of the embodiments will exemplarily be referred to carrier or submount and manufacture method thereof. However, the embodiments are not be used to limit the present invention to carrier or submount.

The present invention provides a carrier, carrier substrate or submount for packaging high power devices. The carrier may include heat sinks for better heat dissipation with thermal expansion consideration. In the present invention, thickness of a substrate is increased to match thermal expansion coefficient of a heat dissipation layer. New materials of adhesion layer is introduced not only to keep high adhesion but also to increase thermal conductivity and to match thermal expansion to other layers. Minute elements also applied to the heat dissipation layer such that the strain and stress thereof can be adjustable to the high power device. A conformal cover layer is provided in the present invention such that heat dissipation layer can be protected from oxidation or chemical erosion much better. New materials of the conformal cover layer are provided for better heat dissipation and thermal expansion match other layers. Moreover, new materials of diffusion layer are introduced such that better heat dissipation is provided.

In the drawings, relative dimensions of each component and among every component may be exaggerated for clarity. Within the following description of the drawings the same or like reference numbers refer to the same or like components or entities, and only the differences with respect to the individual embodiments are described.

Please refer to FIG. 1, one embodiment of a submount or carrier for high power device package or assembly is disclose. A ceramic substrate 100 is provided first and an adhesive layer 101 is formed on three regions for a high power device bonding region, a wire-bonding region, and a heat sink region. A heat dissipation layer 102 is thus formed on the adhesion layer 101 for dissipating heats from the high power device to the heat sink. A conformal cover layer 103 is therefor covering the heat dissipation layer 102 to protect the heat dissipation layer 102 from erosion or being damaged. A diffusion layer 110 and an eutectic bonding layer 112 are formed on the conformal covering layer 103-1 at the first region 100-1.

In this embodiment, the substrate 100 suffers heats from the high power device on the eutectic bonding pad 112 only. Thus most heats will be accumulated under the power device and the substrate 100 will provide less heat conduction efficiency. Thus, this invention is to further improve the this issue.

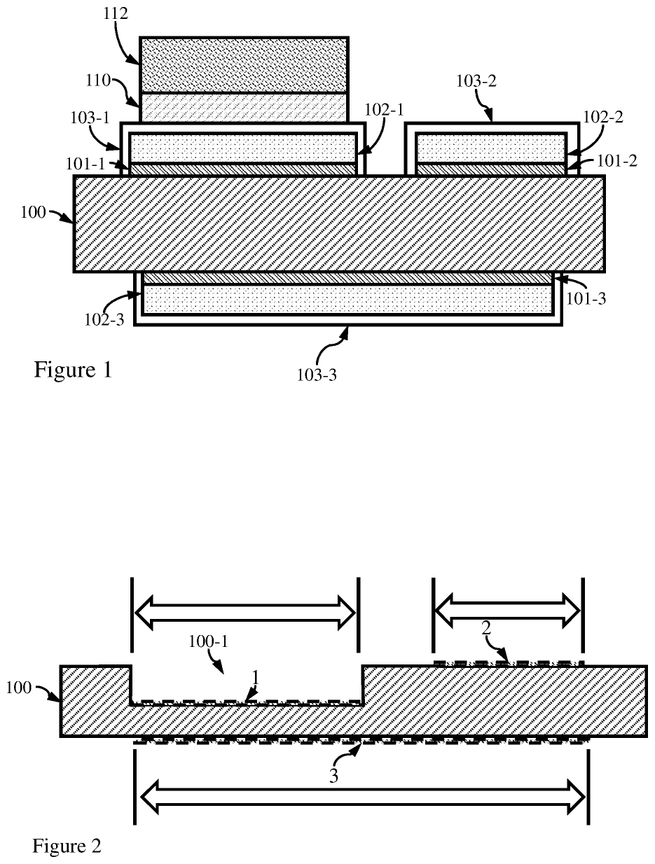

Please refer to FIG. 2, a substrate 100 is provided. The substrate 100 includes high thermal conductive ceramic materials, such as (AlN) Aluminum Nitride, Aluminum Oxide (AlO), Beryllium Oxide (BeO), Silicon Carbide (SiC), Silicon Nitride (SiN), or Boron Nitride (BN), or combination thereof. Ceramic materials are generally brittle, hard, strong in compression, and weak in shearing and tension, which can withstand chemical erosion that occur in other materials subjected to acidic or caustic environments. Ceramics generally can withstand very high temperatures, ranging from 1,000° C. to 1,600° C. In the present invention, a corrosion-resistant, dielectric ceramic material with high thermal conductivity is necessary.

A thickness of the substrate 100 should be high enough to meet heat dissipation requirement and thermal expansion of the power devices. In one embodiment, the substrate 100 has a thickness larger than about 150 μm. However, the preferred dimension of the substrate 100 depends upon the materials thereof and the application of the carrier. Moreover, thermal expansion coefficients of the substrate 100 and the following heat dissipation layer 102 should match that of the high power device.

In the present invention, there are three regions including the first region 1, the second region 2 and the third region 3, wherein the first region 1 and the second region 2 are on the first side of the substrate 100, while the third region 3 is on the second side opposite to the first side. The first region 1 is provided for bonding a high power device, the second region 2 is provided for wire-bonding the high power device, and the third region 3 is provided for heat dissipation or heat sink.

In the present invention, a recession region 100-1 is formed in the first region 1. The recession region 100-1 can be formed be lithography and etching the substrate 100. Depth of the recession region 100-1 can be ranged from 5-130 μm. Preferred depth depends upon heats generated from the high power device.

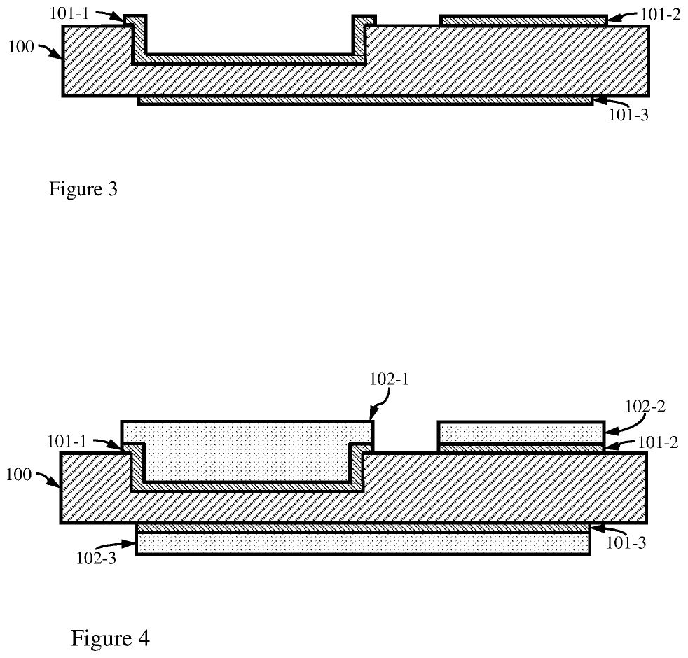

Please refer to FIG. 3, an adhesion layer 101 is formed on the first side and second side of the substrate 100. The adhesion layer 101 is provided for increasing adhesion between the following heat dissipation layer 102 and the substrate 100. Materials of the adhesion layer 101 may include Titanium (Ti), Tungsten (W), Palladium (Pd), Molybdenum (Mo), Rhodium (Rh), Ruthenium (Ru), Platinum (Pt), or alloy thereof. If the a material of the following heat dissipation layer is cupper (Cu), the adhesion layer 101 can be a composite layer, such as Ti/Cu (seed), Ti/Pt/Cu (seed), Mo/Cu (seed), Ti/Mo/Cu (seed), or Mo/TiW/Cu (seed). In one embodiment, Ti provides the main adhesion function, while Cu provides the seed layer for formation of the following heat dissipation layer 102 in the Ti/Cu adhesion layer 101. Different materials of the adhesion layer 101 provide different adhesion function plus heat dissipation function. In a preferred embodiment, a composite adhesion layer, such as Ti/Rh/Cu (seed), Ti/Ru/Cu (seed) or Ti/Pt/Cu (seed), will provide better adhesion function will excellent heat dissipation function.

The adhesion layer 101 can be formed on the substrate 100 by using sputtering, evaporation or electroless plating (chemical plating). The patterned adhesion layer 101, including the first adhesion layer 101-1, second adhesion layer 101-2 and third adhesion layer 101-3, is formed on the first region 1, second region 2 and third region 3 respectively by using conventional lift-off method or conventional lithography with etching method. Thickness of the adhesion layer 101 in the present invention is less than about 5 μm, and preferred about 0.5 μm.

In the present invention, the first adhesion layer 101-1 on the first region 1 is conformally formed in the recession region 101-1, because the following a portion of first heat dissipation layer will be filled inside the recession region 100-1.

Please refer to FIG. 4, a heat dissipation layer 102 is provided on the adhesion layer 101. The heat dissipation layer 102 provides majority heat dissipation function of the carrier in the present invention. Materials of the heat dissipation 102 may include Cu, Nickel (Ni) or alloy thereof, and the heat dissipation layer 102 is formed by using conventional electroless plating. The patterned heat dissipation layer 102, including the first heat dissipation layer 102-1, second heat dissipation layer 102-2 and third heat dissipation layer 102-3, is formed on the first adhesion layer 101-1, second adhesion layer 101-2 and third adhesion layer 101-3 respectively.

In the present invention, the first heat dissipation layer 102-1 at the first region will be filled the recession region. Thus. Thickness of the heat dissipation layer 102-1 is larger than the other two heat dissipation layers 102-2 and 102-3. However, the thickness of the heat dissipation layer 102 will be measured from the top surface of the adhesion layer 101-2.

A thickness of the heat dissipation layer 102 should match to the high power device to be bonded, and can be 1 μm, 30 μm, 70 μm, 100 μm, or larger than about 100 μm. In the present invention, the thickness of the heat dissipation layers 102-1 and 102-2 or the heat dissipation layer 102-3 should be determined to match thermal expansion coefficient of the power device and the substrate 100. First, if a power device is determined, for example a LASER device will be bonded to the carrier, the thickness of the heat dissipation layer 102 is thus determined to match the thermal expansion coefficient of the power device. Then, while the thickness of the heat dissipation layer 102 is determined, the thickness of the substrate 100 will also be determined according to the thermal expansion coefficients of the substrate 100 and the heat dissipation layer 102.

In one embodiment, minute elements can be applied or doped into the heat dissipation layer 102 to lower strain and stress thereof to match thermal coefficient of the high power device to be bonded. Materials of the minute elements may include Cobalt (Co), Iron (Fe), Ni, Silicon (Si), Germanium (Ge), (Diamond like Carbon) DLC, or combination thereof. About less than 10% minute elements can be applied or doped as particles in to the heat dissipation layer 102.

Detailed thickness of the patterned heat dissipation layer 102 is critical in the present invention. The first heat dissipation layer 102-1 as well as the second heat dissipation layer 102-2 should have a thickness close to the third heat dissipation layer 102-3, and thickness difference between the first heat dissipation layer 102-1 as well as the second heat dissipation layer 102-2 and the third heat dissipation layer 102-3 should be less than about 5%. High thermal conductivity and high electrical conductivity of the first heat dissipation layer 120-1, the second heat dissipation layer 102-2 and the third heat dissipation layer 102-3 should be kept similarity.

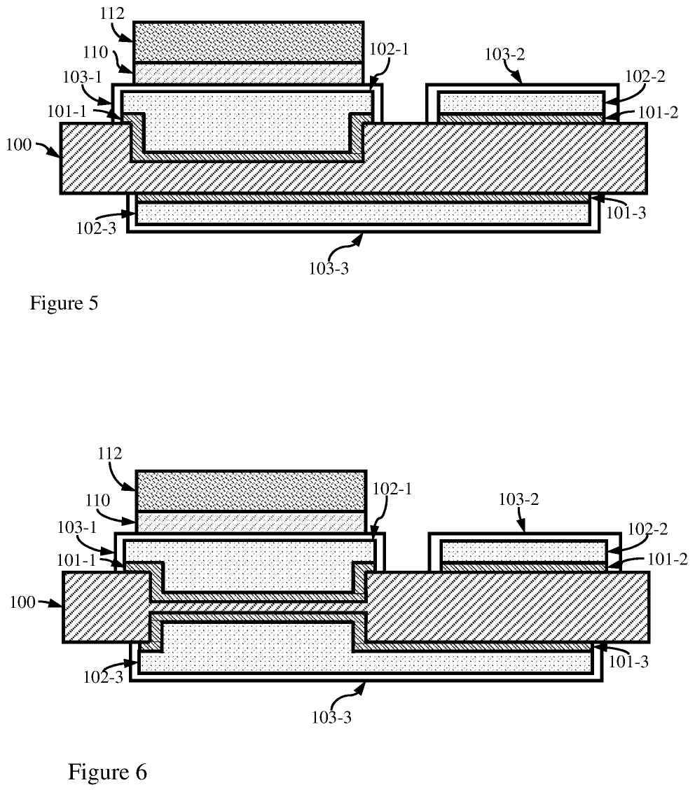

Please refer to FIG. 5, a conformal cover layer 103 is provided to encompass or enclose the heat dissipation layer 102. The conformal cover layer 103 protects the underlying heat dissipation layer 102 from oxidation or etching. Materials of the conformal cover layer 103 may include Ni/Gold (Au), Pt/Au, Pd/Au, Ni/Pt/Au, or Ni/Pd/Au. Formation method of Ni/Au, Pt/Au and Pd/Au may be conventional sputtering or e-gun, while that of Ni/Pt/Au, or Ni/Pd/Au may be conventional electroless plating or plating. The patterned conformal cover layer 103, including the first conformal cover layer 103-1, second conformal cover layer 103-2 and third conformal cover layer 103-3, is formed by using conventional lift-off method or conventional lithography with etching method. In one embodiment, a surface of the second conformal cover layer 103-2 can be roughness such that adhesion between the second conformal cover layer 103-2 and Al wire can be increased. Thickness of the conformal cover layer 103 may be less than about 20 μm. In one embodiment, if Ni exists in the conformal cover layer 103, thickness of the Ni should be less than about 10 μm. In one embodiment, thickness of Au should be less than about 3 μm.

Heat sink may be fastened to the third conformal cover layer 103-3 to dissipate heats from the first heat dissipation layer 102-1 and second heat dissipation layer 102-2, such that heats may not accumulate in the substrate 100 and the power device.

A diffusion barrier layer 110 is provided on the first conformal cover layer 103-1. The diffusion layer 110 protects the conformal cover layer 103-1 from diffusing by the following eutectic layer 112. Materials of the diffusion barrier layer 110 may include Ni, Pt, Rh, Ru, Mo or combination thereof. Formation method of the diffusion barrier layer 110 may be conventional plating, evaporation or sputtering. Thickness of the diffusion barrier layer 110 can be ranged about 0.2 to 3 μm. In one embodiment, thickness of Ni layer should be about 3 μm. In one embodiment, thickness of Pt should be about 0.3 μm. In a preferred embodiment, Rh, Ru or Mo should have better heat dissipation than the Ni or Pt.

An eutectic layer 112 is provided on the diffusion barrier layer 110 as a bonding pad. Material of the eutectic layer 112 can be AuSn, SnAgCu, or InAuBiSn alloy. High power devices, such as LASER diode, IGBT can be bonded on the eutectic layer 112.

In the present invention, not only one recession region can be formed in the substrate 100. Please refer to FIG. 6, a second recession region is formed opposite to the first recession region such that a portion of the third heat dissipation layer 102-3 can be filled inside the second recession region. Thus, heats accumulated in the first heat dissipation layer 102-1 can be conducted to the third heat dissipation layer 102-3 more easily and efficiently.

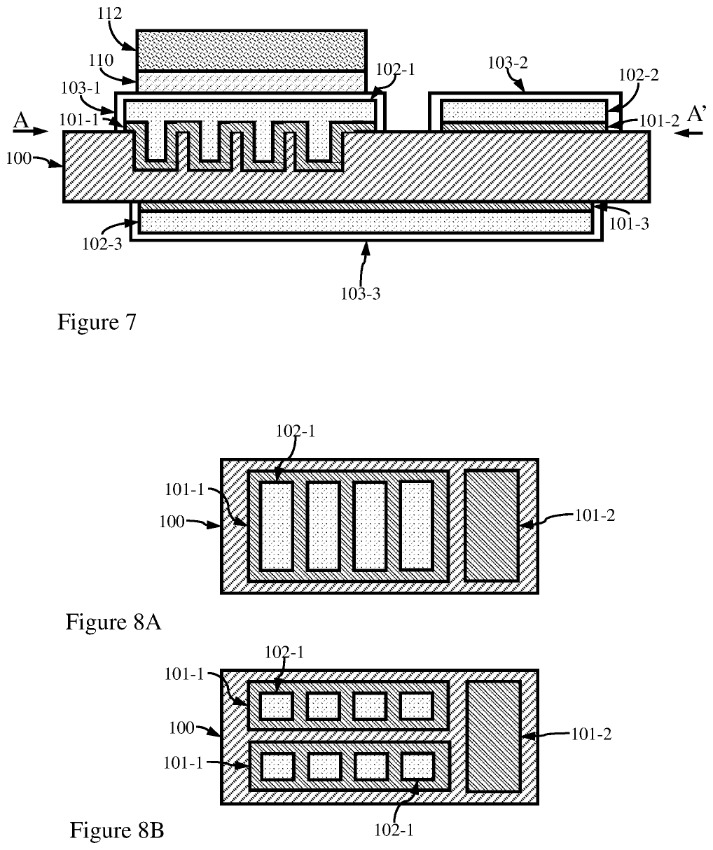

In the present invention, another embodiment is provided also to enhance the heats conducted from the first heat dissipation layer to the second heat dissipation layer. Please refer to FIGS. 7, 8A and 8B, at least two recession regions are formed in the first region 1 of the substrate 100. In one embodiment, there are four recess regions formed in FIG. 7, such that substrate 100 can provide better strain and stress than that of only one recession region. Please also notice that FIG. 7 illustrates a cross-sectional view of the embodiment, there may be more than four recess regions as shown in FIG. 7. This can be illustrated from the top view shown in FIG. 8. In FIG. 8A, there are four recess regions complied with the embodiment as shown in FIG. 7. However, there can be eight recess regions as shown in FIG. 8A.

In the present invention, another embodiment is provided also to enhance the heats conducted from the first heat dissipation layer to the second heat dissipation layer. Please refer to FIG. 9, another multiple recess regions can be formed in the third region of the substrate 100. In FIG. 9, the recess regions in the first region 1 and the recess regions in the third region 3 can be aligned or interlaced with each other (which does not shown in the drawings). Both configurations can provide better heat conduction in the present invention.

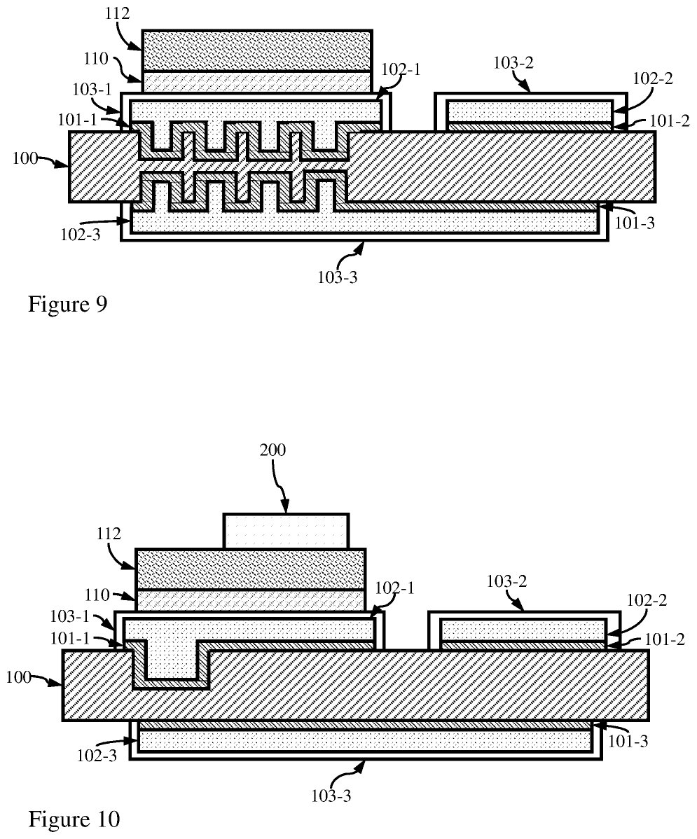

In the present invention, another embodiment is provided also to enhance the heats conducted from the first heat dissipation layer to the second heat dissipation layer. Please refer to FIG. 10, a high power device 200 is bonded to the eutectic bonding layer 112 and a small recess region is formed in the substrate 100. The position of the high power device 200 should be misaligned to the recess region to increase a path of the heat conduction. In this embodiment, the depth of the recess region can be more deeper such that the first heat dissipation layer 102-1 can be more close to the third heat dissipation layer 102-3 at the recess region.

The present invention thus provides better heat dissipation with small package volume, because new materials are introduced to different layers. Heat dissipation is enhanced with compact dimension of the carrier.

The carrier or submount in the present invention has better life and duration in the application, because strain and stress of different layers can be adjustable. Layers of the carrier or submount can be expand all together and less issue incurred by the thermal expansion is avoided.

At least one recess region formed in the substrate in the present invention will provide better heat dissipation efficiency.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A carrier for packaging a power device, comprising:
a thermal conductive ceramic substrate with at least one recess region in a first region;
an adhesion layer patterned on the first region on a first surface of the substrate, a second region on the first surface of the substrate, and a third region on a second surface of the substrate, the second surface opposite to the first surface;
a heat dissipation layer patterned on the adhesion layer;
a conformal cover layer for enclosing the adhesion layer and the heat dissipation layer;
a diffusion barrier layer on the first region of the conformal cover layer; and
an eutectic bonding layer on the diffusion barrier layer.

2. The carrier according to claim 1, wherein a material of the thermal conductive ceramic substrate is selected from a group consisting of AlN, AlO, BeO, SiC, SiN, and BN.

3. The carrier according to claim 2, wherein a material of the adhesion layer includes Cu, Ti, W, Pd, Mo, Rh, Ru, Pt, and alloy thereof.

4. The carrier according to claim 3, wherein the adhesion layer includes a layered structure of Mo/Cu or Ti/Pt/Cu.

5. The carrier according to claim 1, wherein a material of the heat dissipation layer is selected from the group consisting of Cu, Ni, and alloy thereof.

6. The carrier according to claim 5, wherein a minute element is applied to the heat dissipation layer to match thermal expansion of the power device.

7. The carrier according to claim 6, wherein a material of the minute element is selected from a group consisting of Co, Fe, Ni, DLC, C, Si, and Ge.

8. The carrier according to claim 1, further comprising at least one recess region in the third region.

9. The carrier according to claim 1, wherein a position of the first recess region is misaligned to a position of the power device bonded on the eutectic bonding layer.

10. A method for forming a carrier for packaging a power device, comprising:
providing a thermal conductive ceramic substrate with at least recess region in a first region;
forming a patterned adhesion layer on the first region on a first surface of the substrate, a second region on the first surface of the substrate, and a third region on a second surface of the substrate, the second surface opposite to the first surface by sputtering, evaporating, or electroless plating;
forming a heat dissipation layer patterned on the adhesion layer by plating;
forming a conformal cover layer for enclosing the adhesion layer and the heat dissipation layer;
forming a diffusion barrier layer on the first region of the conformal cover layer by sputtering, evaporating, or plating; and
forming an eutectic bonding layer on the diffusion barrier layer.

11. The method according to claim 10, wherein a material of the thermal conductive ceramic substrate is selected from a group consisting of AlN, AlO, BeO, SiC, SiN, and BN.

12. The method according to claim 11, wherein a material of the adhesion layer includes Cu, Ti, W, Pd, Mo, Rh, Ru, Pt, and alloy thereof.

13. The method according to claim 12, wherein the adhesion layer includes a layered structure of Mo/Cu or Ti/Pt/Cu.

14. The method according to claim 10, wherein a material of the heat dissipation layer is selected from the group consisting of Cu, Ni, and alloy thereof.

15. The method according to claim 14, wherein a minute element is applied to the heat dissipation layer to match thermal expansion of the power device, and wherein a material of the minute element is selected from a group consisting of Co, Fe, Ni, DLC, C, Si, and Ge.

16. The method according to claim 13, further comprising at least one recess region in the third region.

17. The method according to claim 16, wherein a portion of the first recess region is misaligned to a position of the power device bonded on the eutectic bonding layer.

18. A carrier for packaging a power device, comprising:
a thermal conductive ceramic substrate with at least one recess region, wherein a thickness of said substrate matches thermal expansion of the power device;
an adhesion layer patterned on a first region on a first surface of the substrate, a second region on the first surface of the substrate, and a third region on a second surface of the substrate, the second surface opposite to the first surface;
a heat dissipation layer patterned on the adhesion layer;
a cover layer for enclosing the adhesion layer and the heat dissipation layer;
a diffusion barrier layer on the first region of the conformal cover layer; and
an eutectic bonding layer on the diffusion barrier layer.

19. The carrier according to claim 18, further comprising at least one recess region in the third region.

20. The carrier according to claim 19, wherein a portion of the first recess region is misaligned to a position of the power device bonded on the eutectic bonding layer.
